(19) United States
(12) Patent Application Publication
(10) Pub. No.: US 2015/0102336 A1
(43) Pub. Date: Apr. 16, 2015

(54) FIELD RELAXATION THIN FILM TRANSISTOR, METHOD OF MANUFACTURING THE SAME AND DISPLAY APPARATUS INCLUDING THE TRANSISTOR

(71) Applicant: Samsung Display Co., Ltd., Yongin-City (KR)

(72) Inventors: Su-Hyoung Kang, Yongin-City (KR); Seung-Hwan Cho, Yongin-City (KR); Yoon-Ho Khang, Yongin-City (KR); Jong-Chan Lee, Yongin-City (KR)

(73) Assignee: Samsung Display Co., Ltd., Yongin-City (KR)

(21) Appl. No.: 14/195,806

(22) Filed: Mar. 3, 2014

(30) Foreign Application Priority Data
Oct. 16, 2013 (KR) 10-2013-0123597

(51) Int. Cl. H01L 27/12; H01L 29/786; H01L 29/66

(52) U.S. Cl. CPC H01L 27/1225; H01L 29/66969; H01L 29/7869
USPC 257/43; 438/104

(57) ABSTRACT

A thin film transistor includes a semiconductor pattern formed on a substrate, the semiconductor pattern being formed of an oxide semiconductor and including a source area, a drain area, and an intermediate area that is formed between the source area and the drain area and includes a plurality of first areas and a second area having higher conductivity than the first areas; a first insulating pattern formed to cover at least the first areas; a second insulating film formed to face the second area, the source area and the drain area; a gate electrode formed on the semiconductor pattern and insulated from the semiconductor pattern by the first insulating pattern and the second insulating film; and source and drain electrodes insulated from the gate electrode and being in contact with the source area and the drain area.

### CROSS-REFERENCE TO RELATED APPLICATION

This application claims priority to and the benefit of Korean Patent Application No. 10-2013-0123597, filed on Oct. 16, 2013, in the Korean Intellectual Property Office, the disclosure of which is incorporated herein in its entirety by reference.

### BACKGROUND

1. Field

One or more embodiments of the present invention relate to a field relaxation thin film transistor, a method of manufacturing the same and a display apparatus including the transistor.

2. Description of the Related Art

A display apparatus may be divided into a display area displaying images and a non-display area around the display area. Various driving circuit units for driving the display area are arranged on the non-display area. A driving circuit unit includes a plurality of thin film transistors and a plurality of capacitors. A plurality of pixels are arranged on the display area and each of the pixels includes a display element and a pixel circuit for driving the display element. The pixel circuit may also include a plurality of thin film transistors and a plurality of capacitors.

### SUMMARY

One or more embodiments of the present invention include a field relaxation thin film transistor, a method of manufacturing the same and a display apparatus including the transistor.

Additional aspects will be set forth in part in the description which follows and, in part, will be apparent from the description, or may be learned by practice of the presented embodiments.

According to one or more embodiments of the present invention, a thin film transistor includes a semiconductor pattern formed on a substrate, the semiconductor pattern being formed of an oxide semiconductor and includes a source area, a drain area, and an intermediate area that is formed between the source area and the drain area and includes a plurality of first areas and a second area having higher conductivity than the first areas; a first insulating pattern formed to cover at least the first areas; a second insulating film formed to face the second area, the source area and the drain area; a gate electrode formed on the semiconductor pattern and insulated from the semiconductor pattern by the first insulating pattern and the second insulating film; and source and drain electrodes insulated from the gate electrode and being in contact with the source area and the drain area.

A first area may be a channel area.

The intermediate area may include the plurality of first areas and at least one second area.

The first area and the second area may be alternately arranged in the intermediate area.

The first area may be arranged adjacently to the source are and the drain area.

The oxide semiconductor may include at least one oxide selected from a group of zinc (Zn), indium (In), gallium (Ga), tin (Sn), cadmium (Cd), germanium (Ge), and hafnium (Hf).

Two or more gate electrodes may be formed, and one of the gate electrodes may be arranged to face one of the first areas.

One of the gate electrodes may be arranged to face the plurality of first areas and the second area.

The first insulating pattern may be formed of an oxide and the second insulating film may be formed of a nitride.

According to one or more embodiments of the present invention, a display apparatus includes a substrate divided into a display area displaying images and a non-display area around the display area; a driving circuit unit arranged on the non-display area, the driving circuit unit comprising a thin film transistor and being electrically coupled to the display area to drive the display area, wherein the thin film transistor includes: a semiconductor pattern formed on a substrate, the semiconductor pattern being formed of an oxide semiconductor and includes a source area, a drain area, and an intermediate area that is formed between the source area and the drain area and includes a plurality of first areas and a second area having higher conductivity than the first areas; a first insulating pattern formed to cover at least the first areas; a second insulating film formed to face the second area, the source area and the drain area; a gate electrode formed on the semiconductor pattern and insulated from the semiconductor pattern by the first insulating pattern and the second insulating film; and source and drain electrodes insulated from the gate electrode and being in contact with the source area and the drain area.

A first area may be a channel area.

The intermediate area may include the plurality of first areas and at least one second area.

The first area and the second area may be alternately arranged in the intermediate area.

The first area may be arranged adjacently to the source are and the drain area.

The oxide semiconductor may include at least one oxide selected from a group of zinc (Zn), indium (In), gallium (Ga), tin (Sn), cadmium (Cd), germanium (Ge), and hafnium (Hf).

Two or more gate electrodes may be formed, and one of the gate electrodes may be arranged to face one of the first areas.

One of the gate electrodes may be arranged to face the plurality of first areas and the second area.

The first insulating pattern may be formed of an oxide and the second insulating film may be formed of a nitride.

According to one or more embodiments of the present invention, a method of manufacturing a thin film transistor includes forming on a substrate a semiconductor pattern formed of an oxide semiconductor; forming a first insulating pattern, formed of an oxide, on a first area that is a portion of an intermediate area of the semiconductor pattern; forming a second insulating film formed of a nitride to cover the first insulating pattern and the semiconductor pattern; forming a gate electrode on at least the first insulating pattern; and forming source and drain electrodes being in contact with edges of the semiconductor pattern.

The second insulating film may be formed of a silicon nitride and the second insulating film may be formed by using a reactant gas comprising hydrogen (H).

### BRIEF DESCRIPTION OF THE DRAWINGS

These and/or other aspects will become apparent and more readily appreciated from the following description of the embodiments, taken in conjunction with the accompanying drawings in which:

FIGS. 1A and 1B are a plane view and a cross sectional view of a thin film transistor according to an embodiment of the present invention;

FIGS. 2A and 2B illustrate experiment results for the holding level of an Ion current according to an embodiment of the present invention as illustrated in FIG. 1B and the holding level of an Ion current according to a comparative example;

FIGS. 3A to 3E are sequential cross sectional views of a method of manufacturing a thin film transistor according to the embodiment of the present invention as illustrated in FIG. 1B;

FIG. 4 is a cross sectional view of a thin film transistor according to another embodiment of the present invention;

FIGS. 5A to 5E are sequential cross sectional views of a method of manufacturing a thin film transistor according to the embodiment of the present invention as illustrated in FIG. 4;

FIG. 6 is a cross sectional view of a thin film transistor according to still another embodiment of the present invention;

FIGS. 7A and 7B are partial cross sectional views of a method of manufacturing a thin film transistor according to the embodiment of the present invention as illustrated in FIG. 6;

FIG. 8 is a plane view of a display apparatus according to an embodiment of the present invention; and

FIG. 9 is a cross sectional view taken along line V-V in FIG. 8.

### DETAILED DESCRIPTION

Since the present invention includes various modifications and embodiments, particular embodiments will be illustrated in the drawings and described in the detailed description in detail. The effects and features of the present invention, and implementation methods thereof will be clarified through the following embodiments described with reference to the accompanying drawings. The present invention may, however, be embodied in different forms and should not be construed as limited to the embodiments set forth herein. As used herein, the term “and/or” includes any and all combinations of one or more of the associated listed items. Expressions such as “at least one of,” when preceding a list of elements, may modify the entire list of elements and may not modify the individual elements of the list.

Embodiments of the present invention are described below in detail with reference to the accompanying drawings and when referring to the drawings, the same or similar components are denoted by the same reference numerals and may not be repetitively described.

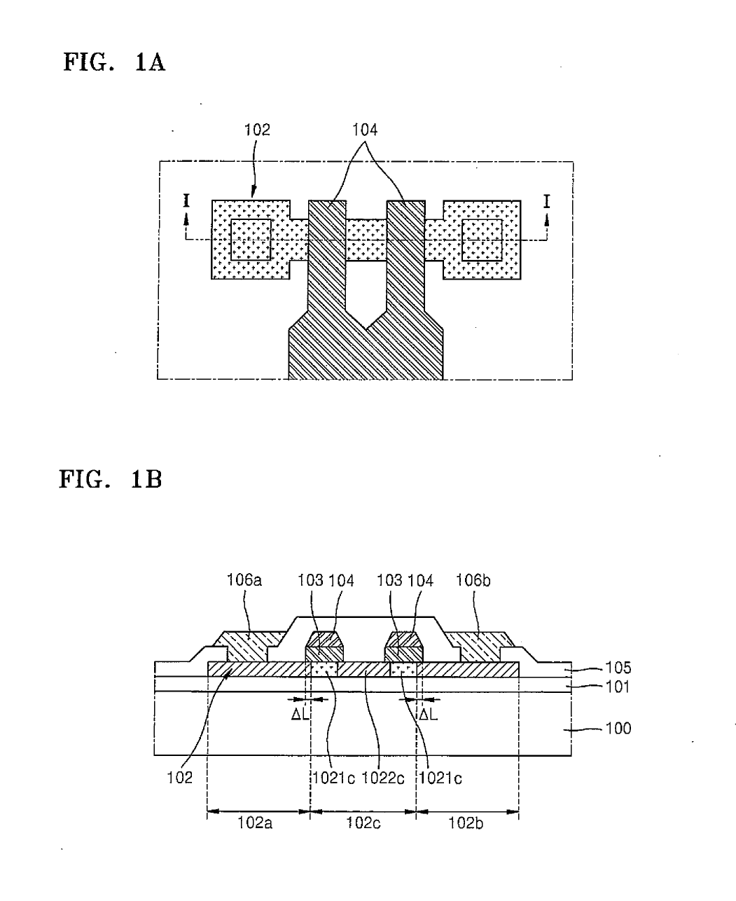

FIGS. 1A and 1B are a plane view and a cross sectional view of a thin film transistor according to an embodiment of the present invention.

The thin film transistor according to an embodiment of the present invention includes a semiconductor pattern 102 that is formed of an oxide semiconductor. The oxide semiconductor may include 12-group to 14-group metal elements such as zinc (Zn), indium (In), gallium (Ga), tin (Sn), cadmium (Cd), germanium (Ge), or hafnium (Hf) and an oxide of a material selected from a combination thereof. For example, the semiconductor pattern may include G-I-Z-O[a(In₂O₃)b(Ga₂O₃)c(ZnO) layers] (where, a, b and c are real numbers, and a≧0, b≧0, and c>0). Such an oxide semiconductor based thin film transistor does not require separate crystallization and doping processes unlike a low temperature poly-silicon (LTPS) based thin film transistor and may be manufactured at a low temperature and its process cost is low.

The thin film transistor in FIGS. 1A and 1B includes the semiconductor pattern 102, a gate electrode 104, and source/drain electrodes 106a and 106b positioned on a substrate 100. The semiconductor pattern 102 includes a source area 102a being in contact with the source electrode 106a, a drain area 102b being in contact with the drain electrode 106b, and an intermediate area 102c arranged between the source area 102a and the drain area 102b. The intermediate area 102c includes a first area 1021c and a second area 1022c. The second area 1022c has higher conductivity than the first area 1021c. The conductivity of the second area 1022c may substantially match with the conductivity of the source area 102a and the drain area 102b. The first are 1021c may correspond to a channel area of the semiconductor pattern 102 of a thin film transistor.

The first area 1021c may be in plural forms and the number of the second area 1022c may be one or more. FIG. 1B shows that the intermediate area 102c includes two first areas 1021c and one second area 1022c, for example. However, an embodiment of the present invention is not limited thereto and the intermediate 102c may include three first areas 1021c and two second areas 1022c. As another example, the intermediate area 102c may include n first areas 1021c and n−1 second areas 1022c (where n is a real number and n≧2). As such, according to embodiments of the present invention, the semiconductor pattern 102 of the thin film transistor includes a plurality of channel areas.

On the other hand, if the first area 1021c is in plural forms, each of the first areas 1021c is arranged adjacently to the source area 102a and the drain area 102b. If the first area 1021c is in plural forms, the first area 1021c and the second area 1022c are alternately arranged in the intermediate area 102c. As illustrated in FIG. 1B, in the case of the semiconductor pattern 102, the source area 102a, a leading first area 1021c, the second area 1022c, a following first area 1021c, and the drain area 102b may be sequentially arranged from the source area 102a to the drain area 102b.

According to an embodiment of the present invention, since the semiconductor pattern 102 of the thin film transistor has the above-described structure, a turn on current (Ion current) of the thin film transistor is not degraded even though the thin film transistor functions as a field relaxation transistor.

Since gate length decreases as more delicate processes are needed, a circuit including the thin film transistor has a defect due to a hot carrier effect according to a strong field on the drain area 102b. In order to prevent it, a field relaxation transistor is inserted in the circuit. The thin film transistor may exhibit a field relation effect if both the first area 1021c and the second area 1022c having higher conductivity than the first area 1021c are arranged on the intermediate area 102c of the semiconductor pattern 102 as shown in FIG. 1B. Also, when the width of the second area 1022c is wider than that of each of the first areas 1021c in a direction of connecting the source area 102a to the drain area 102b, such an effect may be maximized.

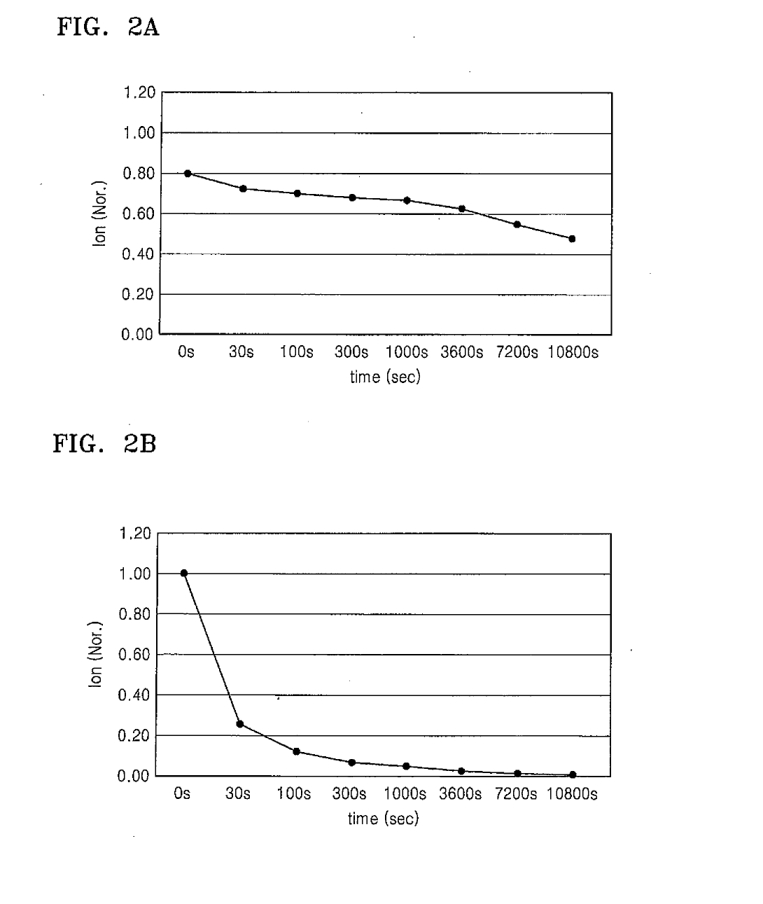

On the other hand, it is perceived through experiments the thin film transistor having the semiconductor pattern 102 as illustrated in FIG. 1B has an effect that an Ion current is not degraded. FIGS. 2A and 2B illustrate experiment results for the holding level of an Ion current according to an embodiment of the present invention and the holding level of an Ion current according to a comparative example. FIGS. 2A and 2B represent a time versus an Ion current value when the drain-source voltage Vds of the thin film transistor is about 10 V. FIG. 2A represents an experiment result for the thin film transistor as shown in FIG. 1B and FIG. 2B represents an experiment result for a bottom gate type oxide semiconductor based thin film transistor.

As shown in FIG. 2A, according to an embodiment of the present invention, it is possible to perceive that an Ion value is maintained even though time passes. It is possible to perceive that about 64% of the initial Ion value is maintained if about 10800 seconds pass. However, it is possible to perceive through the comparative example as shown in FIG. 2B that the Ion value decreases as time passes. If about 10800 seconds pass, only about 4.8% of the initial Ion value is maintained.

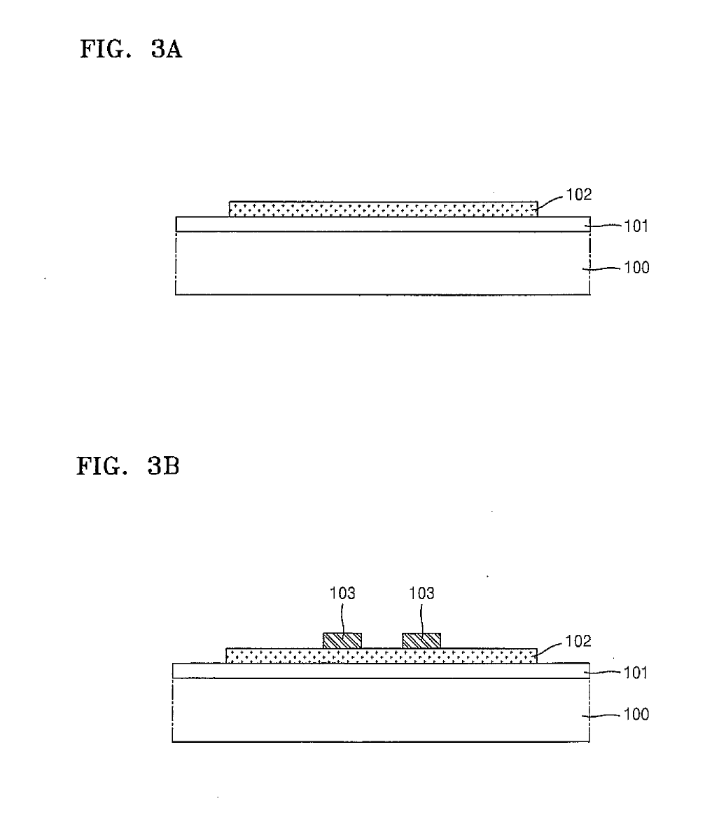

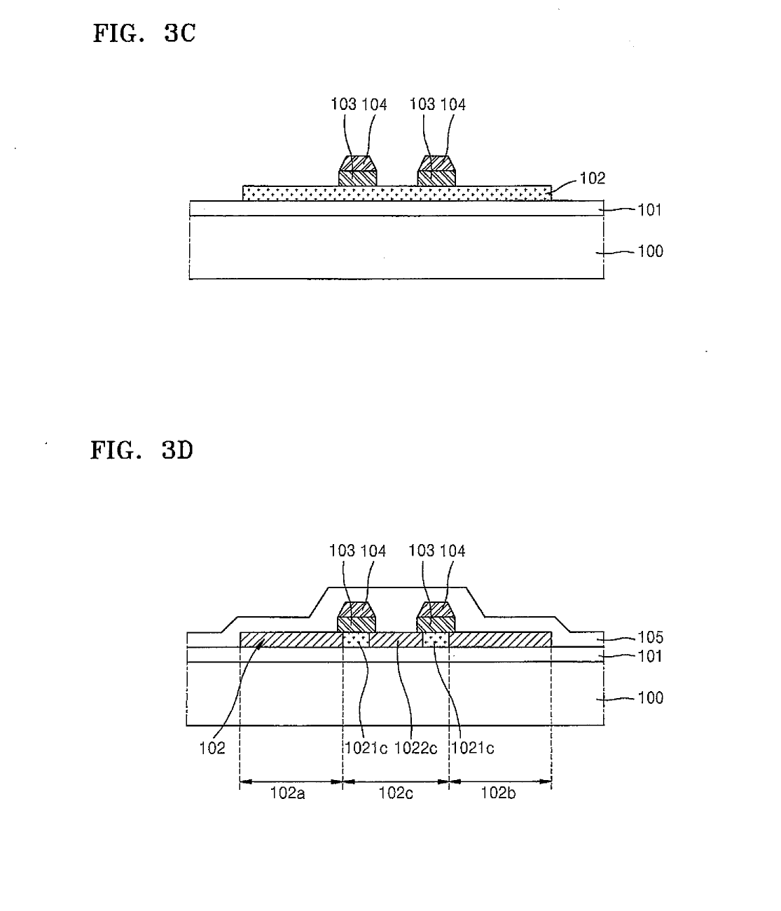

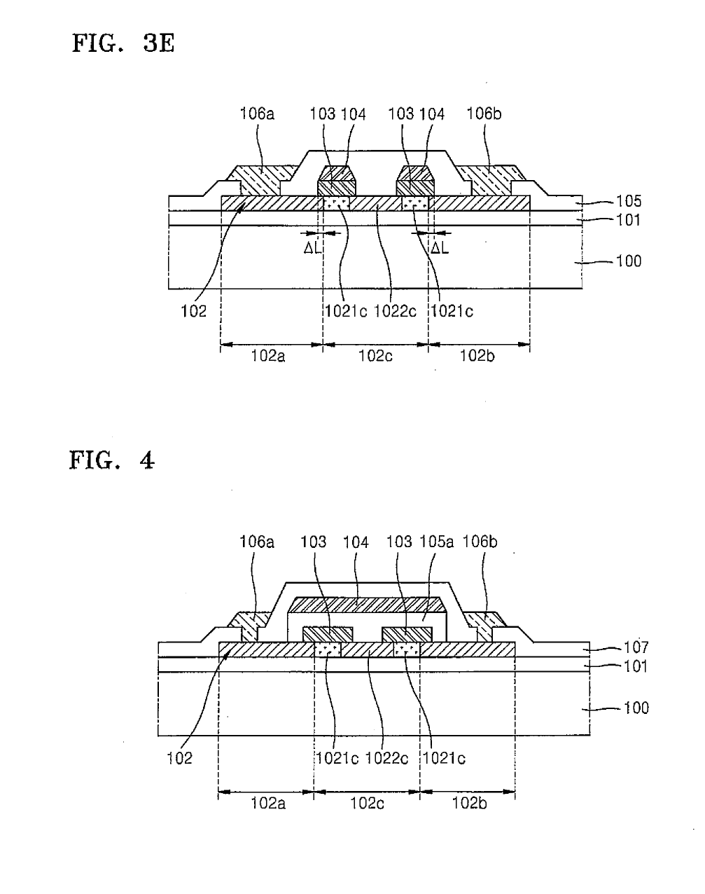

A method of manufacturing a thin film transistor according to an embodiment of the present invention as illustrated in FIG. 1B is discussed below with reference to FIGS. 3A to 3E.

Firstly, referring to FIG. 3A, the semiconductor pattern 102 including an oxide semiconductor is formed on the substrate 100 on top of a buffer layer 101 positioned on the substrate.

Next, referring to FIG. 3B, a first insulating pattern 103 is formed on the first area 1021c that is a portion of the intermediate area 102c of the semiconductor pattern 102. The first insulating pattern 103 includes an oxide and may include a silicon oxide (SiOx) and/or an aluminum oxide (AlOx), for example.

For example, when a first insulating pattern 103 including SiOx and having a thickness of about 500 angstrom is manufactured, a silicon oxide is deposited at a temperature of about 250° C., at pressure of 1500 mTorr, at a power of about 700 W to 900 W by using about 3000 standard cubic centimeter per minutes (SCCM) of a nitrous oxide N₂O gas and about 35 sccm of a silane (SiH₄) gas.

As such, when the first insulating pattern 103 including an oxide is manufactured, the first insulating pattern has little hydrogen because a reactant gas that may include hydrogen (H) is not used for the first insulating pattern 103.

If the first area 1021c is formed in plural forms, the first insulating pattern 103 is formed in plural forms to match with the first areas 1021c. The first insulating pattern 103 functions as a kind of a mask for preventing the first area 1021c from becoming conductive by hydrogen diffusion later. Thus, the first insulating pattern 103 is arranged directly on the first area 1021c to be in direct contact with the first area 1021c.

Next, referring to FIG. 3C, a gate electrode 104 is formed on the first insulating pattern 103. When the first area 1021c is formed in plural forms, the gate electrode 104 is also formed in plural forms. Although FIG. 1B shows that the thin film transistor is in a dual-gate type having two gate electrodes 104, an embodiment of the present invention is not limited thereto and includes multi-gate type thin film transistors that have three or more gate electrodes 104.

Next, referring to FIG. 3D, a second insulating film 105 is formed to cover both the gate electrode and an exposed semiconductor pattern 102. The second insulating film 105 includes a nitride and may include a silicon nitride (SiNx), for example.

For example, when a second insulating film 105 including SiNx and having a thickness of about 300 angstrom to 700 angstrom is manufactured, a silicon nitride may be deposited for about 38 seconds to 49 seconds at a power of about 300 W to 590 W at pressure of 1000 mTorr to 1500 mTorr at a temperature of about 373° C., by using about 1350 sccm to 2240 sccm of an N₂ gas, about 380 sccm to 590 sccm of an NH₃ gas, and about 40 sccm to 130 sccm of an SiH₄ gas and then patterning may be performed by using a photo mask process.

As such, when the second insulating film 105 including a nitride is manufactured, a reactant gas that may include hydrogen (H) in the second insulating film 105 may be used such as an NH₃ gas. Thus, the second insulating film 105 contains a large amount of hydrogen (H) unlike the first insulating pattern 103.

The hydrogen contained in the second insulating film 105 permeates the source area 102a of the semiconductor pattern 102 being in direct contact with the second insulating film 105, the drain area 102b, and the second area 1022c by hydrogen diffusion. An oxide semiconductor generally has high carrier concentration. The reason for this is because oxygen vacancy in the oxide semiconductor works as a cause supplying carrier. On the other hand, if the hydrogen reacts with an oxide, it reduces the oxide and causes oxygen vacancy in the oxide. Thus, since the hydrogen diffused on the second insulating film 105 increases the carrier concentration of the semiconductor pattern 102, the source area 102a, the drain area 102b, and the second area 1022c may be changed to conductors in electrical property. However, the first area 1021c does not change to a conductor, because it is masked by the first insulating pattern 103.

On the other hand, the boundary line between the first area 1021c and the second area 1022c, the boundary line between the first area 1021c and the source area 102a, and the boundary line between the first area 1021c and the drain area 120b may be actually formed under the first insulating pattern 103. This is a result of hydrogen diffusion and the distance delta L (FIG. 3E) between the edge line of the first insulating pattern 103 and the boundary line may be about ⅕ to ⅓ the width of the first insulating pattern 103. For example, when the width of the first insulating pattern 103 is about 5 μm, the delta L may be about 1 μm to 1.5 μm.

Next, referring to FIG. 3E, holes are formed in the second insulating film 105 for exposing the source area 102a and the drain area 102b, the holes are filled to form the source electrode 106a and the drain electrode 106b to be in contact with the source area 102a and the drain area 102b formed on the second insulating film 105. The source electrode 106a and the drain electrode 106b play a role of coupling the thin film transistor according to an embodiment of the present invention to a wiring or another thin film transistor.

FIG. 4 is a cross sectional view of a thin film transistor according to another embodiment of the present invention.

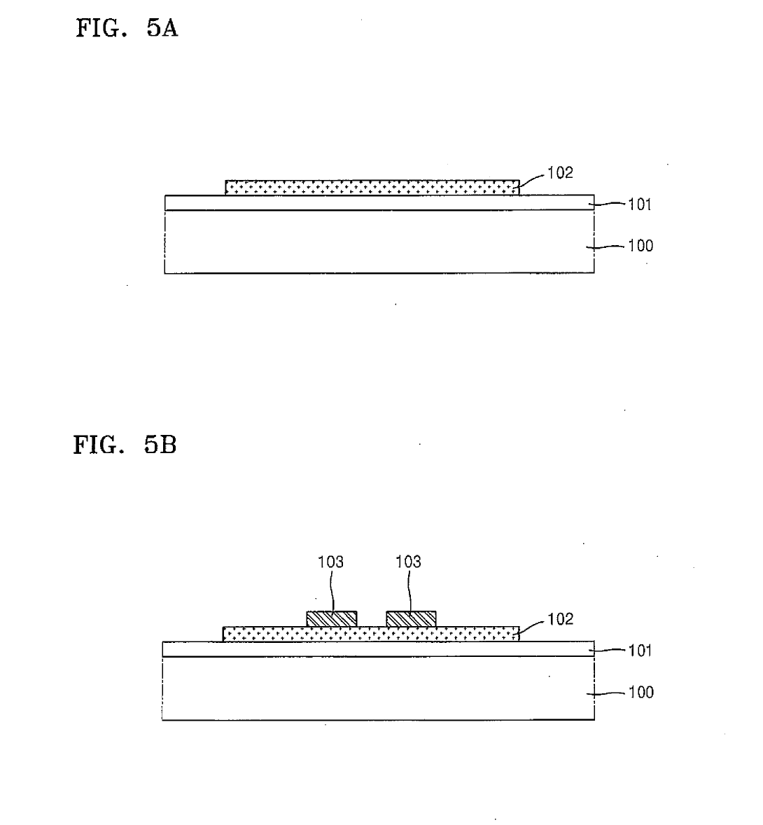

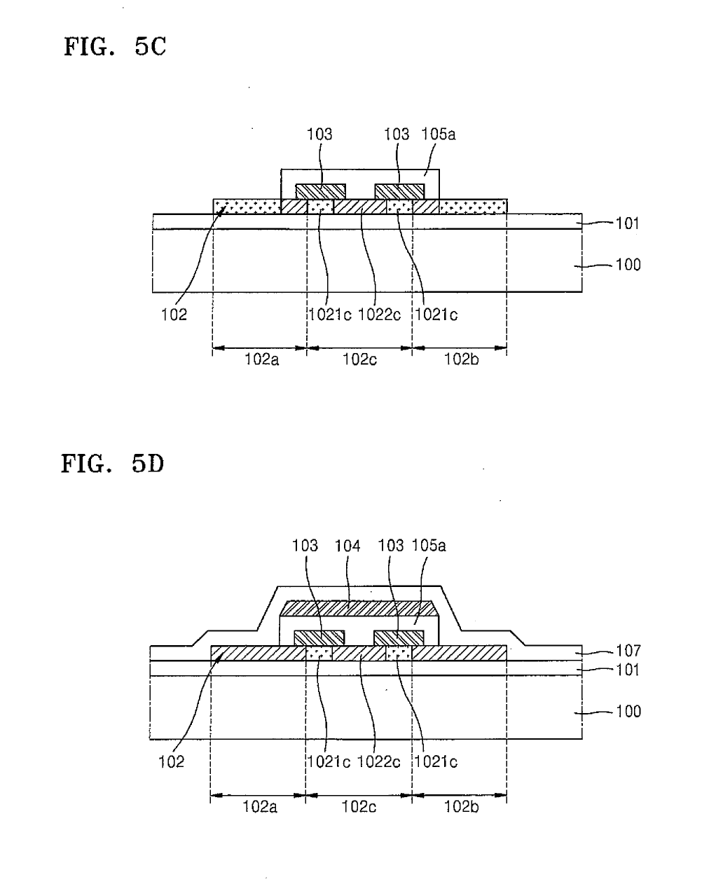

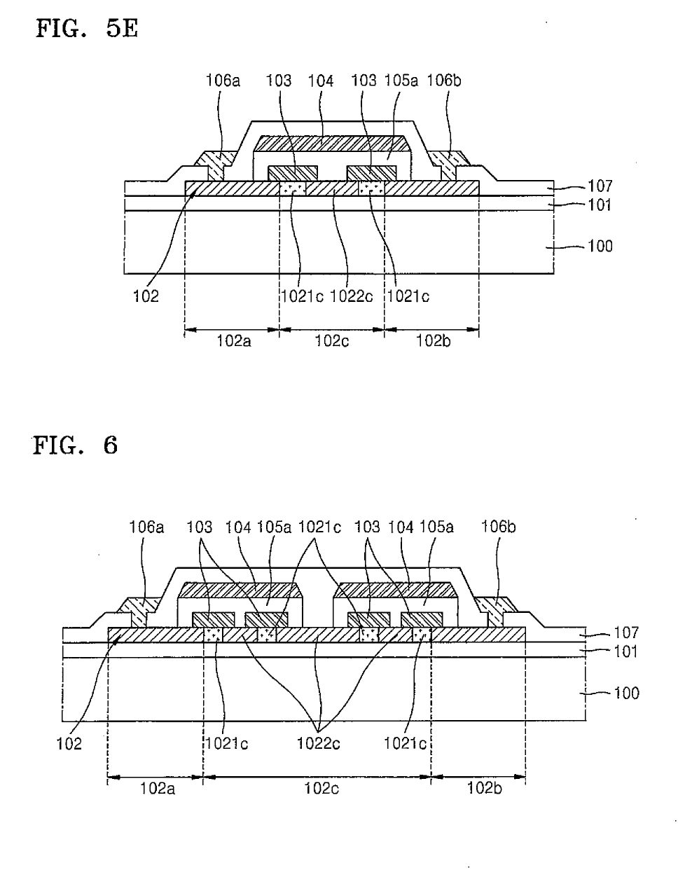

The embodiment according to FIG. 1B illustrates the gate electrode 104 arranged to face one first area 1021c and the gate electrode 104 is formed in plural forms. On the other hand, an embodiment according to FIG. 4 illustrates one gate electrode 104 which is arranged to face a plurality of first areas 1021c and the second area 1022c and only one gate electrode 104 is formed. The embodiment according to FIG. 4 is selectively described on parts different from the embodiment according to FIG. 1B, together with sequential cross sectional views of a manufacturing method of FIG. 4 that are shown in FIGS. 5A to 5E, and is not repetitively described on the same parts.

Referring to FIG. 5A, a semiconductor pattern 102 including an oxide semiconductor is formed on the top of a buffer layer 101.

Referring to FIG. 4, the semiconductor pattern 102 includes a source area 102a, a drain area 102b, and an intermediate area 102c arranged between the source area 102a and the drain area 102b. The intermediate area 102c includes a first area 1021c and a second area 1022c. The second area 1022c has higher conductivity than the first area 1021c. The conductivity of the second area 1022c may substantially match with the conductivity of the source area 102a and the drain area 102b. The first area 1021c may be in plural forms and the number of the second area 1022c may be one or more.

Referring to FIG. 5B along with FIG. 4, first insulating patterns 103 are formed on the first areas 1021c, respectively. The first insulating pattern 103 includes an oxide and may include a silicon oxide (SiOx) and/or an aluminum oxide (AlOx), for example.

Referring to FIG. 5C, a second insulating pattern 105a is formed to cover a portion of an exposed semiconductor pattern 102 and the first insulating patterns 103. The second insulating pattern 105a includes a nitride similar to the second insulating film 105 of FIG. 1B, and may include a silicon nitride (SiNx), for example. Thus, a portion of the source area 102a, a portion of the drain area 102b, and the second area 1022c may be changed to conductors by hydrogen diffusion of hydrogen that is contained in the second insulating pattern 105a, in terms of an electrical property.

Referring to FIG. 5D, a gate electrode 104 is formed on the second insulating pattern 105a and a third insulating film 107 is formed to cover all of the gate electrode 104, the exposed source area 102a and an exposed drain area 102b. The third insulating film 107 includes a nitride similar to the second insulating film 105 of FIG. 1B, and may include a silicon nitride (SiNx), for example. Thus, remaining portions of the source area 102a and the drain area 102b may be changed to conductors by hydrogen diffusion of hydrogen that is contained in the third insulating film 107, in terms of an electrical property.

Referring to FIG. 5E, after forming the third insulating film 107, holes for exposing the source area 102a and the drain area 102b are formed in the insulating film and are to be filled to form the source electrode 106a and the drain electrode 106b to be in contact with the source area 102a and the drain area 102b formed on the third insulating film 107.

In the embodiment according to FIG. 4, the second insulating pattern 105a is formed in the same shape as the gate electrode 104 but the present invention is not limited thereto. The second insulating pattern 105a may not be patterned like the second insulating film 105 of FIG. 1B but may have a form of a film that entirely covers a substrate 100.

The embodiment according to FIG. 4 does not have a multi-gate electrode structure but may have a characteristic that an Ion value is not degraded because the thin film transistor exhibits a field effect like the embodiment according to FIG. 1B. The embodiment according to FIG. 4 may be employed to a design that is difficult to implement a multi-gate electrode.

FIG. 6 is a cross sectional view of a thin film transistor according to still another embodiment of the present invention.

The embodiment according to FIG. 6 is formed by combining the embodiment according to FIG. 1B with the embodiment according to FIG. 4. FIG. 6 illustrates that one gate electrode 104 is arranged to face a plurality of first areas 1021c and a second area 1022c and the gate electrode 104 is formed in plural forms.

A plurality of first areas 1021c and at least one second area 1022c are arranged to face each gate electrode 104, the number of the gate electrode 104 is two or more and the gate electrode 104 is a multi-gate type.

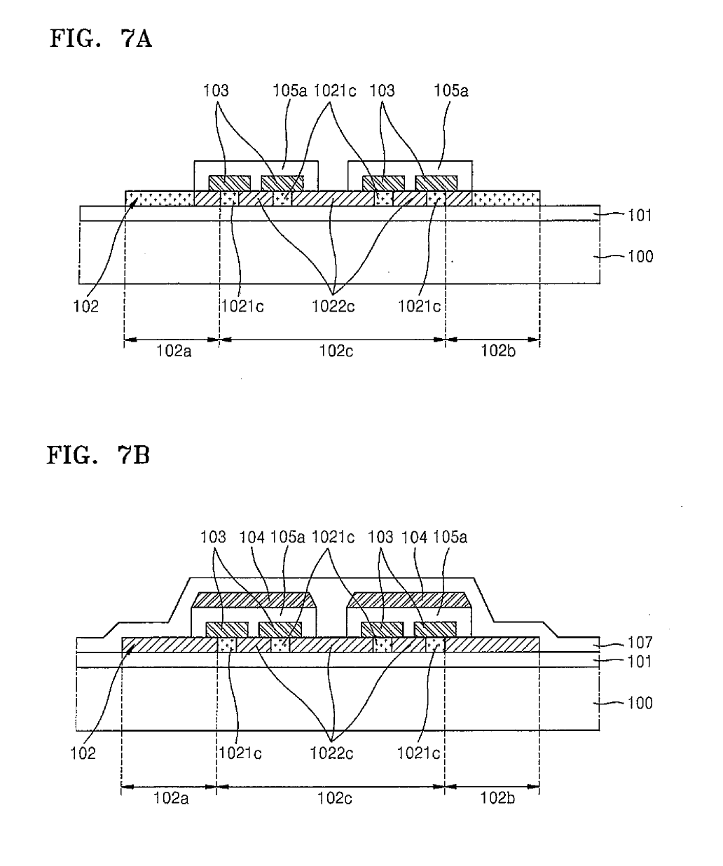

The manufacturing method for the embodiment of FIG. 6 is described with reference to FIGS. 7A and 7B. As shown in FIG. 7A, first insulating patterns 103 including oxides are formed on first areas 1021c respectively and a plurality of second insulating patterns 105a including nitrides are formed to cover the first insulating patterns 103. Thus, a portion of the source area 102a, a portion of the drain area 102b, and the second area 1022c may be changed to conductors by hydrogen diffusion of hydrogen that is contained in the second insulating pattern 105a, in terms of an electrical property.

In addition, as shown in FIG. 7B, a gate electrode 104 is formed on the second insulating pattern 105a and a third insulating film 107 including a nitride is formed to cover all of the gate electrodes 104, an exposed source area 102a and drain area 102b. Thus, remaining portions of the source area 102a and the drain area 102b may be changed to conductors by hydrogen diffusion of hydrogen that is contained in the third insulating pattern 107, in terms of an electrical property.

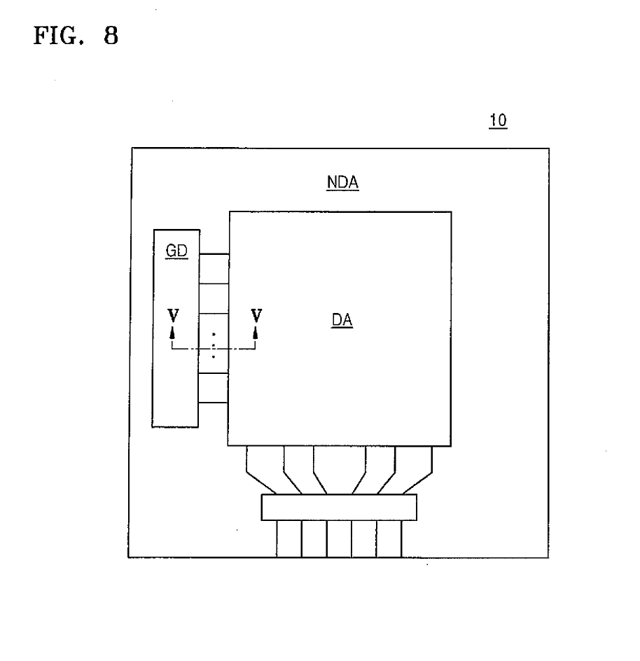

FIG. 8 is a plane view of a display apparatus 10 according to an embodiment of the present invention.

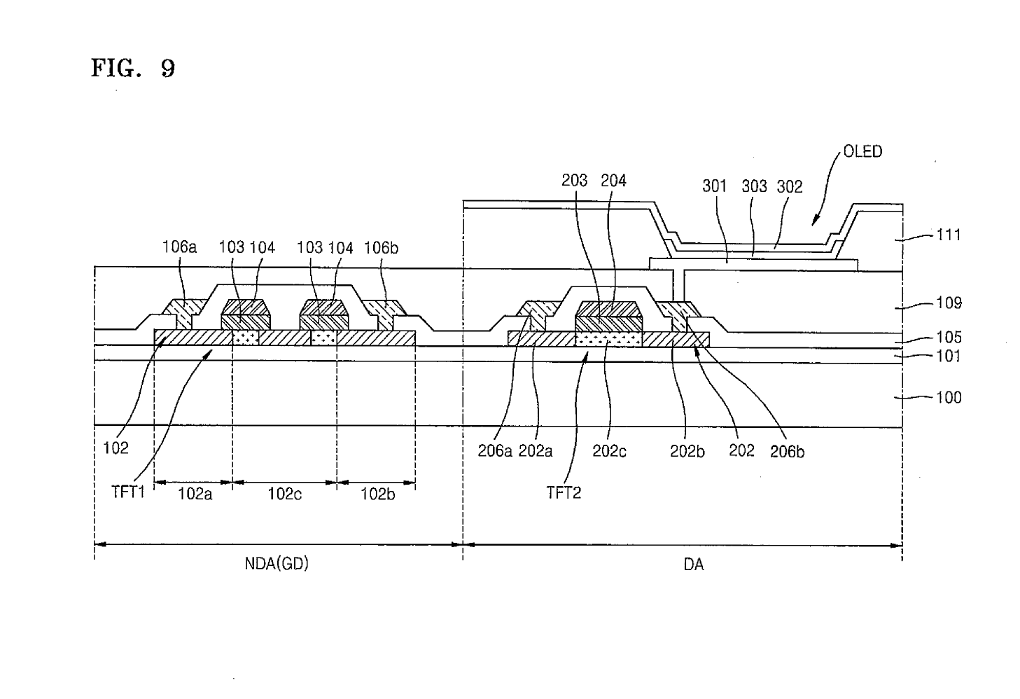

The display apparatus 10 according to an embodiment of the present invention is a kind of a light-emitting type display apparatus and may be an organic light-emitting display apparatus that uses an organic light-emitting diode (OLED) in which an organic light-emitting layer 303 (see FIG. 9) is disposed between anodes 301 and 302 (see FIG. 9). However, an embodiment of the present invention is not limited thereto and may be a kind of a light-receiving type display apparatus, such as a liquid crystal display apparatus that uses a liquid crystal device. The organic light-emitting display apparatus is described below as an example of the display apparatus.

The organic light-emitting display apparatus includes a bottom emission type that emits light toward a substrate 100, a top emission type that emits light toward the opposite side of the substrate 100, and a dual emission type that emits light toward both the substrate 100 and the opposite side of the substrate 100 but the present invention is not limited thereto.

The display apparatus includes a display area DA displaying images on the substrate, and a non-display area NDA arranged around the display area DA and not displaying images. The display area DA includes a plurality of pixels. Each pixel includes the OLED emitting light and a pixel circuit unit that is coupled to and drives the OLED. The pixel circuit unit includes at least two thin film transistors and at least one capacitor. The pixel circuit unit is electrically coupled to a gate line, a data line, and a power line.

A driving circuit unit for driving the display area DA is disposed on the non-display area NDA. For example, the driving circuit unit may be included in a gate driver GD. The gate driver GD is coupled to the gate lines of the display area and supplies a gate signal to the display area. The driving circuit unit may include a plurality of thin film transistors and a plurality of capacitors.

FIG. 9 is a cross sectional view taken along line V-V in FIG. 8.

In the following, a thin film transistor included in the pixel circuit unit is referred to as a pixel thin film transistor TFT2 and a thin film transistor included in the driving pixel unit is referred to as a driving thin film transistor TFT1. FIG. 9 schematically shows one pixel thin film transistor TFT2 arranged on the display area DA, OLED coupled thereto, and the driving thin film transistor TFT1 arranged on the non-display area NDA.

According to an embodiment of the present invention, some thin film transistors needing a field relation function among a plurality of thin film transistors that are included in the driving circuit unit employs at least one of thin film transistor structures according to embodiments of FIGS. 1B, 4 and 6. When a bottom gate type thin film transistor is employed as the field relaxation thin film transistor of the driving circuit unit and a high drain-source voltage Vds is applied, there is a drawback in that the turn on Ion of the transistor is degraded and the display apparatus has a defect. However, if the thin film transistor according to an embodiment of the present invention is employed as the driving thin film transistor TFT1 for the driving circuit unit, an Ion current is not degraded due to a second area 1022c having higher conductivity than a first area 1021c arranged on an intermediate area 102c of the semiconductor pattern 102.

FIG. 9 employs the thin film transistor according to the embodiment of FIG. 1B for the driving circuit unit but the present invention is not limited thereto and may also employ the thin film transistor according to the embodiment of FIG. 4 or 6.

On the other hand, the pixel thin film transistor TFT2 may employ a general form of a thin film transistor where an area having high conductivity is not arranged, for an intermediate part 202c of an active pattern 202. The active pattern 202 of the pixel thin film transistor TFT2 includes a source part 202a, a drain part 202b, and an intermediate part 202c therebetween, and the conductivity of the intermediate part 202c is lower than that of the source/drain parts 202a and 202b. In FIG. 9, a gate electrode, a source electrode and a drain electrode are denoted by reference numerals 204, 206a and 206b, respectively.

Although FIG. 9 shows a top gate type pixel thin film transistor, the present invention is not limited thereto and may also employ a bottom gate type. Also, if the pixel circuit unit needs a field relaxation function, the thin film transistors according to the embodiments of FIGS. 1B, 4 and 6 may also be used as the pixel thin film transistor.

On the other hand, the OLED is disposed on a planarization film 109 covering the pixel thin film transistor TFT2 and a pixel defining film 111 for defining each light-emitting area is also disposed.

According to embodiments of the present invention, since a thin film transistor that relaxes field and does not degrade the turn-on Ion of a transistor is provided, the quality of a display apparatus is enhanced.

Although the present invention is described with reference to embodiments illustrated in the drawings, it will be understood that the embodiments are merely exemplary and a person skilled in the art may make various variations. Thus, the real technical scope of the present invention shall be determined by the technical spirit of the accompanying claims.

What is claimed is:

1. A thin film transistor comprising:
a semiconductor pattern formed on a substrate, the semiconductor pattern being formed of an oxide semiconductor and including a source area, a drain area, and an intermediate area that is formed between the source area and the drain area and includes a plurality of first areas and a second area having higher conductivity than the first areas;
a first insulating pattern formed to cover at least the first areas;
a second insulating film formed to face the second area, the source area and the drain area;
a gate electrode formed on the semiconductor pattern and insulated from the semiconductor pattern by the first insulating pattern and the second insulating film; and
source and drain electrodes insulated from the gate electrode and being in contact with the source area and the drain area.

2. The thin film transistor of claim 1, wherein the first area is a channel area.

3. The thin film transistor of claim 1, wherein the intermediate area comprises the plurality of first areas and at least one second area.

4. The thin film transistor of claim 3, wherein the first area and the second area are alternately arranged in the intermediate area.

5. The thin film transistor of claim 3, wherein the first area is arranged adjacently to the source are and the drain area.

6. The thin film transistor of claim 1, wherein the oxide semiconductor comprises at least one oxide selected from a group of zinc (Zn), indium (In), gallium (Ga), tin (Sn), cadmium (Cd), germanium (Ge), and hafnium (Hf).

7. The thin film transistor of claim 1, wherein two or more gate electrodes are formed, and one of the gate electrodes is arranged to face one of the first areas.

8. The thin film transistor of claim 7, wherein one of the gate electrodes is arranged to face the plurality of first areas and the second area.

9. The thin film transistor of claim 1, wherein the first insulating pattern is formed of an oxide and the second insulating film is formed of a nitride.

10. A display apparatus comprising:
a substrate divided into a display area to display images and a non-display area around the display area;
a driving circuit unit arranged on the non-display area, the driving circuit unit comprising a thin film transistor and being electrically coupled to the display area to drive the display area, wherein the thin film transistor comprising:
a semiconductor pattern formed on a substrate, the semiconductor pattern being formed of an oxide semiconductor and including a source area, a drain area, and an intermediate area that is formed between the source area and the drain area and includes a plurality of first areas and a second area having higher conductivity than the first areas;
a first insulating pattern formed to cover at least the first areas;
a second insulating film formed to face the second area, the source area and the drain area;
a gate electrode formed on the semiconductor pattern and insulated from the semiconductor pattern by the first insulating pattern and the second insulating film; and
source and drain electrodes insulated from the gate electrode and being in contact with the source area and the drain area.

11. The display apparatus of claim 10, wherein the first area is a channel area.

12. The display apparatus of claim 10, wherein the intermediate area comprises the plurality of first areas and at least one second area.

13. The display apparatus of claim 12, wherein the first area and the second area are alternately arranged in the intermediate area.

14. The display apparatus of claim 12, wherein the first area is arranged adjacently to the source are and the drain area.

15. The display apparatus of claim 10, wherein the oxide semiconductor comprises at least one oxide selected from a group of zinc (Zn), indium (In), gallium (Ga), tin (Sn), cadmium (Cd), germanium (Ge), and hafnium (Hf).

16. The display apparatus of claim 10, wherein two or more gate electrodes are formed, and one of the gate electrodes is arranged to face one of the first areas.

17. The display apparatus of claim 16, wherein one of the gate electrodes is arranged to face the plurality of first areas and the second area.

18. The display apparatus of claim 10, wherein the first insulating pattern is formed of an oxide and the second insulating film is formed of a nitride.

19. A method of manufacturing a thin film transistor, the method comprising:
forming on a substrate a semiconductor pattern formed of an oxide semiconductor;
forming a first insulating pattern formed of an oxide, on a first area that is a portion of an intermediate area of the semiconductor pattern;
forming a second insulating film formed of a nitride to cover the first insulating pattern and the semiconductor pattern;
forming a gate electrode on at least the first insulating pattern; and
forming source and drain electrodes in contact with edges of the semiconductor pattern.

20. The method of claim 19, wherein the second insulating film is formed of a silicon nitride and the second insulating film is formed by using a reactant gas comprising hydrogen (H).
